(19) United States
(12) Patent Application Publication
(10) Pub. No.: US 2005/0086564 A1
(43) Pub. Date: Apr. 21, 2005

(54) Multi-chip module and method for testing

(76) Inventors: Gerd Frankowsky, Hohenkirchen (DE); Peter Ossimitz, Munchen (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 10/924,565

(22) Filed: Aug. 24, 2004

(30) Foreign Application Priority Data
Aug. 25, 2003 (DE) DE 103 39 054.5

(51) Int. Cl. H01L 23/02; G11C 29/00

(52) U.S. Cl. 714/718

(57) ABSTRACT

A multi-chip module having an integrated semiconductor mass memory and a logic chip is disclosed. In accordance with one aspect of the invention, the integrated logic chip includes electrically programmable links or other non-volatile memory for permanently storing memory cells of the memory chip identified as defective. In the event of accesses to the memory chip the address present is compared with the stored addresses of the defective cells by a comparator and, if appropriate, a changeover is made from the memory chip to a volatile memory provided for this purpose in the logic chip, in which redundant memory cells are formed. The result is a significantly increased yield and a reduced test complexity, particularly in mass production.

### REFERENCE TO RELATED APPLICATIONS

This application claims the benefit of the priority date of German application DE 103 39 054.5, filed on Aug. 25, 2003, the contents of which are herein incorporated by reference in their entirety.

### FIELD OF THE INVENTION

The present invention relates to a multi-chip module and to a method for testing a multi-chip module.

### BACKGROUND OF THE INVENTION

A multi-chip module normally comprises a plurality of integrated semiconductor circuits, so-called chips. By way of example, it is customary for such a multi-chip module to have one or a plurality of integrated semiconductor memories and also a logic chip. The integrated semiconductor memory or memories is or are in this case usually designed as volatile memories in the form of Dynamic Random Access Memories, DRAM. For driving the memory chips the logic chip is normally coupled thereto via a data bus, an address bus and one or more command lines.

On account of the physical conditions during the fabrication of integrated semiconductor chips in mass production methods it is practically inevitable that some of the multiplicity of memory cells in integrated semiconductor memories will be defective actually during or after production. In order to avoid problems resulting from this during the operation of the memories, it is customary, during the production of the integrated semiconductor memory, to identify the defective memory cells and replace them by redundant memory cells that are likewise present on the integrated semiconductor memory. For this purpose, the addresses of the defective memory cells are permanently stored on the integrated semiconductor chip, for example by so-called laser fuses being permanently reprogrammed by external application of energy pulses. However, laser fuses can only be programmed during and no longer after the production of the semiconductor memory.

In particular, with such memory chips at the module level, individual memory cells identified as defective can no longer be repaired, that is to say be replaced by redundant memory cells.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

In one aspect of the present invention a multi-chip module is provided in which a test and a repair of defective memory cells in an integrated semiconductor memory are possible even after the end of the production of the module. In another aspect of the present invention, a test method is provided in which a so-called bare die handling may be obviated.

According to the invention, a multi-chip module is provided having at least one integrated semiconductor memory chip having a multiplicity of memory cells and an integrated circuit chip that is coupled to the at least one integrated semiconductor memory chip, and that comprises at least one non-volatile memory for permanently storing an address of a defective memory cell in the integrated semiconductor memory. The integrated circuit chip further comprises a comparator that is coupled to the at least one non-volatile memory and that compares an address present at an input, in the event of write/read accesses to the integrated semiconductor memory, with the address stored in the at least one non-volatile memory. In addition, the integrated circuit chip comprises a volatile memory and a multiplexer that is driven by the comparator in such a way that in a manner dependent on the comparison result in the comparator a write/read access is effected either to a memory cell in the integrated semiconductor memory chip or to a memory cell in the volatile memory portion of the integrated circuit chip.

With regard to another aspect of the invention, a method for testing a multi-chip module comprising an integrated semiconductor memory chip and an integrated circuit chip comprises testing the functionality of memory cells in the integrated semiconductor memory chip, and storing addresses of memory cells of the integrated semiconductor memory chip identified as defective in the integrated circuit chip.

In accordance with the invention, redundant memory cells for the integrated semiconductor memory are not arranged in the latter, but rather in the integrated circuit. The integrated circuit is normally embodied as a logic chip. The logic chip is usually present anyway in a multi-chip module. Since one or a plurality of electrically programmable links or other non-volatile memories are provided in the integrated circuit, in contrast to the integrated semiconductor memory, they can be programmed even after the mounting of the chips to form a multi-chip module.

During a test of the entire multi-chip module toward the end or after production, an identification and repair of defective memory cells of the integrated semiconductor memory may be carried out during a so-called back-end test. This makes it possible to significantly improve the yield during the module test. The microcontroller that is normally present anyway in the logic chip, that is to say in the integrated circuit, and the volatile memory that is likewise normally present anyway in the integrated circuit may be used as well in order to effect the module test.

Test and repair may be initiated and/or executed by an external chip. As an alternative or in addition, test and repair may also be carried out in the context of a self-test, a so-called POST, Power On Self Test.

An additional advantage results from the fact that defective memory cells can be identified and repaired even during normal operation. For this purpose a special test program which, for example after the activation of the integrated circuit, tests the integrated semiconductor memory and automatically repairs defective memory cells that are possibly present may be stored in the integrated circuit, for example in a microcontroller therein. In this example case, a repair is to be understood as the permanent storage of the addresses of the defective memory cells in such a way that in the event of accesses to the defective memory cells a diversion to intact, redundant memory cells is effected.

An even further increase in the yield results from the fact that the identification and repair of individual defective memory cells in the integrated semiconductor memory may be effected in the context of the back-end test of the entire multi-chip module even after a burn-in method step for the entire module so that it is possible to concomitantly register the statistically increased failure rate directly at the beginning of the service life of the integrated semiconductor memory and to repair failures of the memory cells governed thereby likewise at the end of the production of the module.

Overall, with the principle proposed when using memory chips in multi-chip modules, for the integrated semiconductor memories a comparatively complex KGD (Known Good Die) test method for the memory chip on its own is no longer necessary. Moreover, it is additionally advantageous that the problems of so-called bare die handling for the hitherto required production steps of burn-in and back-end test memory are obtained.

The multi-chip module may comprise one or more integrated circuits with the above-described features, which are also referred to as logic chips.

The non-volatile memory is preferably designed as an electrically programmable link for permanently storing a data item. In the case of such an electrically programmable link the conductivity state of the programmable link is permanently changed over from low impedance to high impedance or from high impedance to low impedance by application of an energy pulse. Depending on whether the application of an electrical energy pulse to the programmable link effects a high-impedance conductivity state or a low-impedance conductivity state, the link is referred to as a fuse or an anti-fuse. Overall, electrically programmable links are referred to as e-fuses.

As an alternative the non-volatile memory may also be embodied as a flash memory or as a so-called PROM programmable read-only memory, or EPROM, erasable programmable read-only memory.

A microcontroller is preferably provided for the sequence control of the testing of the memory cells of the integrated semiconductor memory and the storing of the addresses of the memory cells identified as defective in the associated programmable links. The microcontroller can be accommodated in a separate integrated circuit or alternatively be provided in the integrated circuit in which the programmable links are also arranged.

Instead of the microcontroller a digital signal processor can also be provided.

As an alternative or in addition, the test may be carried out directly or indirectly by means of a separate test device. In this case the addresses of defective memory cells are identified in a test device outside the multi-chip module and subsequently written to the multi-chip module for programming.

As an alterative or in addition, the test may be carried out by means of a built-in memory chip self-test, a so-called BIST. In this case, as in the case of the microcontroller-controlled test as well, the addresses of defective memory cells are identified and stored within the multi-chip module.

The volatile memory in the integrated circuit is preferably embodied as a static random access memory. Such a memory is also designated by the abbreviation SRAM. In accordance with the principle proposed, the redundant memory cells for memory cells in the actual integrated semiconductor memory identified as defective are formed in the volatile memory of the logic chip.

As an alternative, the volatile memory may also comprise one or a plurality of registers for memory purposes.

A plurality of signal connections are preferably provided between the integrated circuit and the semiconductor memory, for the purpose of coupling the latter. These preferably comprise a bidirectional data bus and a unidirectional address bus. Moreover, one or a plurality of command lines may be provided by means of which the integrated circuit can drive the semiconductor memory.

The semiconductor memory itself is preferably likewise embodied as a volatile memory and designed for example as a dynamic random access memory.

As an alternative, the at least one semiconductor memory may also be a non-volatile memory.

The comparator may be constructed as a comparator using integrated circuit technology. As an alternative, however, it is also possible to map the comparator function in a program code processed by a microprocessor. For example the integrated circuit may comprise the microprocessor or the latter may be arranged in a separate integrated circuit.

The multi-chip module, MCM, may also be embodied as a so-called multi-chip package, MCP, or as a system in package, SIP.

### BRIEF DESCRIPTION OF THE DRAWINGS

The invention is explained in more detail below using an exemplary embodiment with reference to the figures, in which:

FIG. 1 shows a block diagram illustration of an exemplary multi-chip module according to one aspect of the present invention; and

FIG. 2 shows an exemplary method according to another aspect of the present invention.

### DETAILED DESCRIPTION OF THE INVENTION

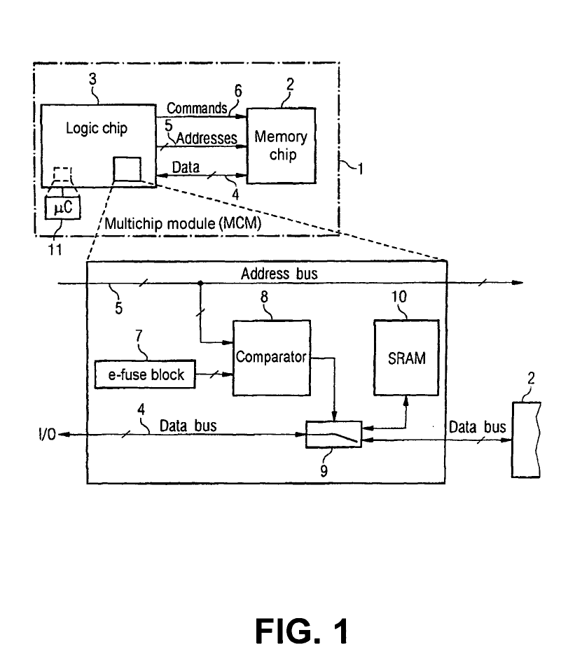

FIG. 1 shows a multi-chip module 1 according to one aspect of the present invention. The multi-chip module 1 comprises by way of example only one integrated semiconductor memory 2 and an integrated circuit 3 embodied as a logic chip. The integrated semiconductor memory 2 and the integrated circuit 3 are separate integrated circuits. The latter are applied on a common carrier, for example a printed circuit board, in order to form the multi-chip module 1. The integrated circuit 3 and the integrated semiconductor memory 2 are connected to one another via a bidirectional data bus 4 and an address bus 5 from the integrated circuit 3 to the semiconductor memory 2 and a command line 6 which likewise connects the integrated circuit 3 to the integrated semiconductor memory 2.

The integrated circuit 3 comprises a block 7 having a multiplicity of electrically programmable links embodied as so-called e-fuses. The latter serve to store addresses of memory cells in the integrated semiconductor memory 2 that are identified as defective. A comparator 8 has two inputs, of which one is connected to the block with the programmable links 7 and the other is connected to the address bus 5. The output of the comparator controls a multiplexer 9. The multiplexer 9 optionally connects an input/output interface of the data bus 4 to the integrated semiconductor memory 2 or to a volatile memory 10 in the integrated circuit 3. The volatile memory 10 is embodied, for example, as a static random access memory, SRAM. The integrated circuit 3 also comprises a microcontroller 11.

The addresses of the memory cells of the integrated semiconductor memory 2 that are identified as defective are permanently stored in the block 7 with the programmable links. If a write or read access is then effected via the data bus 4 to or from the integrated semiconductor memory 2 then the assigned address of the memory cell array in the memory chip 2 is compared with the address stored in the block having the programmable links 7 by means of the comparator 8. If the comparator 8 finds a correspondence, that is to say that the address present on the address bus 5 is assigned to a defective memory cell of the integrated semiconductor memory 2, then the multiplexer does not switch the input/output interface I/O to the integrated semiconductor memory 2 but rather changes over to the volatile memory 10 in the integrated circuit 3. If, otherwise, a defective memory cell is not involved, that is to say that the comparator finds no correspondence, then the integrated semiconductor circuit 2 is accessed as usual.

The storage of the addresses of defective memory cells in the bank of programmable links in the block 7 of the multi-chip module may be effected for example under the control of the microcontroller 11 in the event of an activation of the circuit. The comparator 8 for all write/read accesses compares the memory address present with all the addresses stored in the block of programmable links 7, and controls the multiplexer 9 depending on the comparison result.

Compared with a conventional multi-chip module with an integrated semiconductor memory, only a few components have to be added in accordance with the principle proposed, inter alia the multiplexer 9, the volatile memory 10, the address comparator 8 and the block having electrically programmable links 7.

In accordance with the invention, a defect correction of individual memory cells or small groups of memory cells of the integrated semiconductor memory 2 in the integrated circuit 3 is effected without any problems.

In accordance with another aspect of the present invention, a back-end test of the memory chip 2 alone is no longer necessary, rather the back-end test may take place at the level of the multi-chip module.

A relatively complex known good die (KGD) test of the memory chip 2 in the multi-chip module 1 may be obviated in accordance with yet another aspect of the present invention. Since in multi-chip modules the failures in the integrated semiconductor memory 2 normally relate to individual memory cells, and not entire word or bit lines, that is to say that only individual bits are defective, the repair can be effected without any problems by means of the invention.

A particular advantage of the present invention resides in the fact that, even when only so-called laser fuses, for example, are provided for repairing defective memory cells in the integrated semiconductor chip, the repair is possible at the module level even after the end of production, for example, after packaging and module mounting.

According to the invention, the integrated memory chip 2 need not be subjected to a separate burn-in test and also does not have to be mounted onto a temporary wafer carrier for this purpose. Rather, in accordance with the invention, the so-called burn-in method step including the programming of the e-fuses in block 7 does not take place until after the mounting of the chips 2, 3 at the module level. The complicated mounting and demounting of the wafer with the integrated semiconductor memories embodied for example as DRAMS onto special carriers for testing is also obviated as a result.

Testing the functionality of the memory cells in the integrated semiconductor memory 2 and carrying out the redundancy concept by storing the addresses of defective memory cells of the memory chip 2 in the logic chip 3 may be carried out in one act at the end of the production of multi-chip module 1. Overall, this distinctly simplifies the method for fabricating multi-chip modules comprising integrated mass memories. Moreover, the result is a more cost-effective production with, in addition, a significantly increased yield.

In alternative embodiments to the example shown it also lies within the scope of the invention to permit a plurality of integrated semiconductor memories to be driven by a common integrated circuit embodied as a logic chip.

In alternative embodiments, the microcontroller 11 can also be designed as a digital signal processor. The microcontroller 11 may also be provided as a separate integrated chip.

Instead of the e-fuse bank 7 a flash memory may also be provided in another embodiment of the invention.

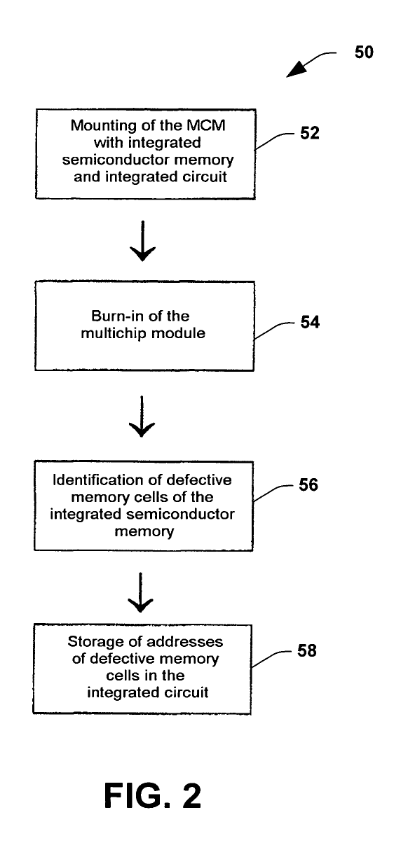

FIG. 2 shows one exemplary method 50 for testing and for repairing a multi-chip module MCM according to another aspect of the present invention. While the exemplary method 50 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention.

As proposed and described above, the test and repair 50 of the present invention is advantageously effected on the already mounted multi-chip module toward the end of or after production in the context of a so-called back-end test. Accordingly, a first act 52 effects the mounting of the integrated semiconductor memory and the integrated circuit and also further chips that are present if appropriate to form the multi-chip module. Afterward, a burn-in of the module is carried out in a second act 54. As a result, the statistically increased failure rate at the beginning of the service life is concomitantly registered by the subsequent test and cells identified as defective are concomitantly repaired. A third act 56 effects testing of the functionality of the memory cells in the integrated semiconductor memory. A redundancy concept that comprises the storing of the addresses of memory cells of the integrated semiconductor memory chip identified as defective in the integrated circuit is also carried out at 58 in this example.

Advantageously, a microcontroller present in the integrated circuit, which is also referred to as a logic chip, and a volatile memory may be concomitantly used for the sequence control of testing and for carrying out the redundancy concept. Moreover, defect identification is possible even in the context of normal operation, for example, by means of a POST, power on self-test.

According to the principle proposed, complex bare die handling is obviated for the production steps of burn-in and back-end test memory at the die level during production. Moreover, the yield is increased with the principle proposed.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

### List of Reference Symbols

1 Multi-chip module
2 Integrated semiconductor memory chip
3 Logic chip
4 Data bus
5 Address bus
6 Command line
7 E-fuse bank
8 Comparator
9 Multiplexer
10 Volatile memory
11 Microcontroller
I/O Interface

1. A multi-chip module, comprising:
at least one integrated semiconductor memory chip comprising a plurality of memory cells; and
an integrated circuit chip coupled to the at least one integrated semiconductor memory chip, wherein the integrated circuit chip comprises:
at least one non-volatile memory configured to permanently store an address of a defective memory cell in the integrated semiconductor memory chip;
a comparator coupled to the at least one non-volatile memory configured to compare an address present at an input, in the event of write/read accesses to the integrated semiconductor memory chip, with the address stored in the at least one non-volatile memory;
a volatile memory; and
a multiplexer that is driven by the comparator in such a way that in a manner dependent on the comparison result in the comparator a write/read access is effected either to a memory cell in the integrated semiconductor memory chip or to a memory cell in the volatile memory.

2. The multi-chip module as claimed in claim 1, wherein the at least one non-volatile memory comprises a fusible link configured to be programmed by an electrical energy pulse applied thereto.

3. The multi-chip module as claimed in claim 1, wherein the at least one non-volatile memory comprises a flash memory.

4. The multi-chip module as claimed in claim 1, wherein the integrated circuit chip further comprises a microcontroller configured to test the plurality of memory cells in the integrated semiconductor memory chip and store the addresses of memory cells identified as defective in the at least one non-volatile memory.

5. The multi-chip module as claimed in claim 1, wherein the volatile memory in the integrated circuit chip comprises a static random access memory.

6. The multi-chip module as claimed in claim 1, wherein the volatile memory in the integrated circuit chip comprises one or a plurality of memory registers.

7. The multi-chip module as claimed in claim 1, wherein the integrated circuit chip is coupled to the semiconductor memory chip via a bidirectional data bus.

8. The multi-chip module as claimed in claim 1, wherein the integrated circuit chip is coupled to the semiconductor memory chip via an address bus for the communication of memory addresses thereto.

9. The multi-chip module as claimed in claim 1, wherein the integrated circuit chip is coupled to the semiconductor memory chip via at least one command line.

10. The multi-chip module as claimed in claim 1, wherein the at least one semiconductor memory chip comprises a volatile memory.

11. A method for testing a multi-chip module comprising an integrated semiconductor memory chip and an integrated circuit chip, comprising:
testing a functionality of memory cells in the integrated semiconductor memory chip; and
storing addresses of memory cells of the integrated semiconductor memory chip identified as defective in the integrated circuit chip.

12. The method as claimed in claim 11, wherein the storing of addresses of memory cells of the integrated semiconductor memory chip identified as defective in the integrated circuit chip occurs after a mounting of the integrated semiconductor memory chip and the integrated circuit chip to form the multi-chip module.

13. The method as claimed in claim 11, wherein the testing of the functionality of memory cells in the integrated semiconductor memory chip and the storing of addresses of memory cells of the integrated semiconductor memory chip identified as defective in the integrated circuit chip occurs after the mounting of the integrated semiconductor memory chip and the integrated circuit chip to form the multi-chip module.

14. The method as claimed in claim 11, wherein testing the functionality of memory cells in the integrated semiconductor memory chip comprises testing the functionality of the memory cells using a microcontroller and a volatile memory both provided in the integrated circuit chip.

15. The method as claimed in claim 11, wherein the testing of the functionality of memory cells in the integrated semiconductor memory chip and storing addresses of memory cells of the integrated semiconductor memory chip identified as defective in the integrated circuit chip occurs within a power on self test.

16. The method as claimed in claim 11, wherein the testing of the functionality of memory cells in the integrated semiconductor memory chip and storing the addresses of memory cells of the integrated semiconductor memory chip identified as defective in the integrated circuit chip occurs after carrying out a burn-in procedure for the entire multi-chip module.

17. The method as claimed in claim 11, wherein the storing of addresses of memory cells of the integrated semiconductor memory chip identified as defective comprises storing the addresses in a non-volatile memory within the integrated circuit chip.

18. A method of repairing defective memory cells associated with an integrated semiconductor memory chip residing within a multi-chip module, comprising:
sending an address associated with a write/read access of a memory cell within the integrated semiconductor memory chip to an integrated circuit chip within the multi-chip module;
comparing the address to one or more addresses within a non-volatile memory in the integrated circuit chip, wherein the one or more addresses are associated with identified defective memory cells within the semiconductor memory chip; and
employing data within a volatile memory within the integrated circuit chip for the write/read access of the memory cell within the integrated circuit if the address matches one of the one or more addresses within the non-volatile memory.

19. The method of claim 18, wherein employing data within the volatile memory comprises driving a multiplexer based on the comparison to select data associated with a location within the volatile memory within the integrated circuit chip if the address matches one of the one or more addresses within the non-volatile memory.

20. The method of claim 18, further comprising employing data within the semiconductor memory chip associated with the address if the address does not match one of the one or more addresses in the non-volatile memory.
